(19) United States
(12) Patent Application Publication
(10) Pub. No.: US 2007/0063349 A1
(43) Pub. Date: Mar. 22, 2007

(54) Interconnect structure and method of manufacturing the same

(76) Inventors: Tsui-Lien Kao, Gukeng Township (TW); Huei-Ju Tsai, Tainan City (TW); Shyan-Yhu Wang, Taichung City (TW); Jy-Hwang Lin, Hsinchu City (TW)

Correspondence Address: J C PATENTS, INC., 4 VENTURE, SUITE 250, IRVINE, CA, 92618, US

(21) Appl. No.: 11/231,264

(22) Filed: Sep. 19, 2005

(51) Int. Cl. H01L 21/4763; H01L 21/44; H01L 23/48

(52) U.S. Cl. 257/753; 438/628; 438/631; 438/644; 438/654; 257/755; 257/757; 257/E21.584

(57) ABSTRACT

The invention is directed to a method for manufacturing an interconnect structure suitable for a substrate having a semiconductor device formed thereon, wherein the semiconductor device possesses a metal silicide layer predetermined as an electrically connecting region. The method comprises steps of forming a conformal adhesion layer over the substrate, forming a dielectric layer on the conformal adhesion layer and then performing a chemical mechanical polishing process to planarize the dielectric layer. Further, an opening penetrating through the dielectric layer and the conformal adhesion layer is formed, wherein the opening exposes a portion of the metal silicide layer. A conductive plug is formed in the opening.

### BACKGROUND OF THE INVENTION

1. Field of Invention

The present invention relates to a semiconductor device and a method for manufacturing the same. More particularly, the present invention relates to an interconnect structure and a method for manufacturing the same.

2. Description of Related Art

With the increasing of the integration and the decreasing of the line width of the semiconductor device, the process window for each material layer is decreased. With the increasing of the number of the material layers formed over a substrate, the evenness of the topmost surface is poor so that the difficulty for performing the deposition process, the photolithography process and the etching process is increased.

In order to resolve this problem caused by the uneven topmost surface of the material layer, the planarization process is developed. Taking the dielectric layer as an example, the planarization process includes thermal flow, etching back and spin-on glass. Currently, the chemical mechanical polishing process is introduced and becomes an indispensable thin film planarization technique.

In some semiconductor manufacturing processes, before the contact window is formed, it is necessary to perform a chemical mechanical polishing process on the inter-layer dielectric layer to increase the process window for the later performed processes. However, the chemical mechanical polishing process leads to the formation of the voids between the inter-layer dielectric layer and the conductive layer. Furthermore, after the contact window is formed, a dipping process with the use of a hydrofluoric acid solution is usually performed to clean up the impurity over the substrate. Nevertheless, the fluoride intrudes the aforementioned voids and remains on the bottom of the contact window. Therefore, the voids and the remaining fluoride lead to the electrical problem of the later formed contact plug.

### SUMMARY OF THE INVENTION

Accordingly, at least one objective of the present invention is to provide a method for manufacturing an interconnect structure for increasing the process window.

At least another objective of the present invention is to provide an interconnect structure for increasing the product yield.

To achieve these and other advantages and in accordance with the purpose of the invention, as embodied and broadly described herein, the invention provides a method for manufacturing an interconnect structure suitable for a substrate having a semiconductor device formed thereon, wherein the semiconductor device possesses a metal silicide layer predetermined as an electrically connecting region. The method comprises steps of forming a conformal adhesion layer over the substrate, forming a dielectric layer on the conformal adhesion layer and then performing a chemical mechanical polishing process to planarize the dielectric layer. Further, an opening penetrating through the dielectric layer and the conformal adhesion layer is formed, wherein the opening exposes a portion of the metal silicide layer. A conductive plug is formed in the opening.

In the present invention, the conformal adhesion layer is formed from silicon nitride by a low pressure chemical vapor deposition (LPCVD).

In the present invention, the thickness of the conformal adhesion layer is about 200-500 angstroms.

In the present invention, the material of the dielectric layer is selected from a group consisting of silicon oxide, phosphorous silicon glass and boron-phosphorous silicon glass.

In the present invention, the semiconductor device can be a logic device operated at a high voltage level.

In the present invention, the metal silicide layer is located at a gate electrode of the semiconductor device and the gate electrode is made of a doped polysilicon.

In the present invention, the metal silicide layer is located at a source/drain region of the semiconductor device.

In the present invention, the metal silicide is made of tungsten silicide.

In the present invention, before the conductive plug is formed, a conformal barrier layer is formed over the substrate. The conformal barrier layer is made of titanium/titanium nitride.

In the present invention, the conductive plug is made of tungsten.

The present invention also provides an interconnect structure on a substrate having a logic device formed thereon, wherein the logic device possesses a metal silicide layer predetermined as an electrically connecting region. The interconnect structure comprises a conformal adhesion layer, a dielectric layer and a conductive plug. The conformal adhesion layer is located over the substrate. The dielectric layer is located on the conformal adhesion layer. The conductive plug is penetrating through the dielectric layer and the conformal adhesion layer, wherein the conductive plug is electrically connected to the metal silicide layer.

In the present invention, the conformal adhesion layer is formed from silicon nitride.

In the present invention, the thickness of the conformal adhesion layer is about 200-500 angstroms.

In the present invention, the logic device can be operated at a high voltage level.

In the present invention, the metal silicide layer is located at a gate electrode of the logic device.

In the present invention, the metal silicide layer is located at a source/drain region of the logic device.

In the present invention, the metal silicide layer is made of tungsten silicide.

In the present invention, the conformal adhesion layer is located between the metal silicide layer and the dielectric layer both of which possess poor ability to adhere to each other so that the metal silicide layer and the dielectric layer can be protected from being ripped off from each other due to the shear stress caused by the CMP process. Therefore, the phenomenon that the void and the defects exist between the metal silicide layer and the dielectric layer can be avoided and the electrical performance of the device is stable.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1C are cross-sectional views illustrating a method for manufacturing an interconnect structure according to one preferred embodiment of the present invention.

FIG. 2 is a cross-sectional view showing an interconnect structure according to one preferred embodiment of the present invention.

FIG. 3 is a testing counts-contact resistance diagram.

### DESCRIPTION OF THE PREFERRED EMBODIMENTS

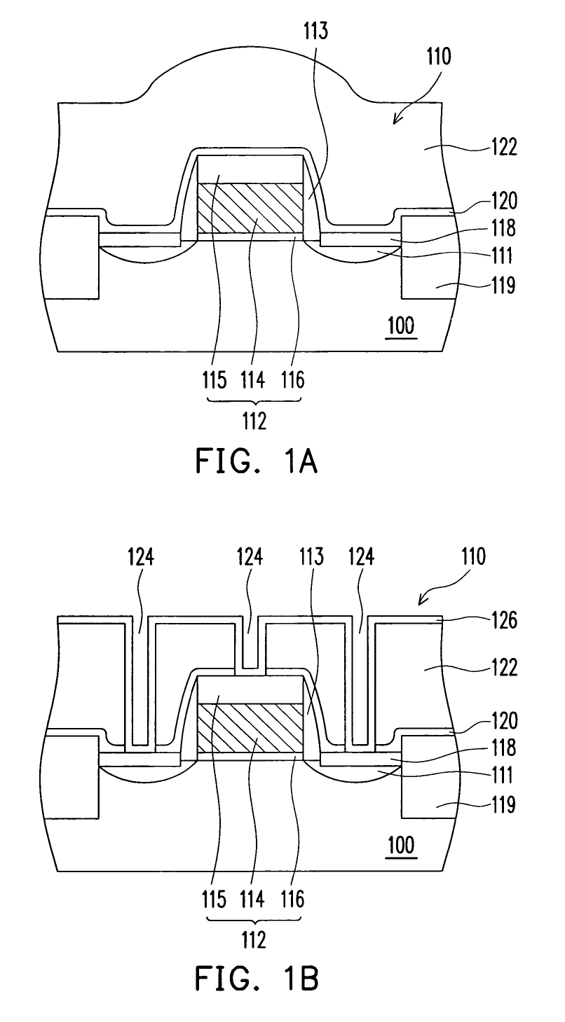

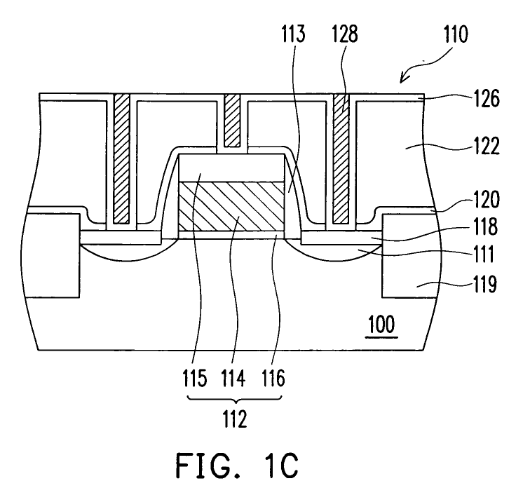

FIGS. 1A through 1C are cross-sectional views illustrating a method for manufacturing an interconnect structure according to one preferred embodiment of the present invention. As shown in FIG. 1A, a substrate 100 is provided. The substrate 100 can be, for example but not limited to, a silicon substrate. Furthermore, the substrate 100 has a semiconductor device 110 formed thereon, wherein the semiconductor device 110 can be, for example but not limited to, a logic device. More preferably, the semiconductor device 110 is a logic device, such as a driver of the thin-film-transistor liquid crystal display, operated at a high voltage level. In this preferred embodiment, only one semiconductor device 110 is used to illustrate spirit of the present invention. However, in the application, there are several semiconductor devices are disposed on the substrate 100. Moreover, the semiconductor device 110 is composed of a source/drain region 111, a gate structure 112 and a spacer 113.

It should be noticed that the gate structure 112 is located on the substrate 100. The gate structure 112 comprises a gate electrode 114 and a metal silicide layer 115 which is located on the gate electrode 114. The gate electrode 114 can be, for example but not limited to, made of doped polysilicon and the metal silicide layer 115 can be, for example but not limited to, made of tungsten silicide. Further, the gate structure 112 comprises a tunnel dielectric layer 116 located between the gate electrode 114 and the substrate 100.

The source/drain region 111 is located in the substrate 100 adjacent to the gate structure 112. There is a metal silicide layer 118 formed on the source/drain region 111. Moreover, the metal silicide layer 118 can be, for example but not limited to, made of tungsten silicide.

Also, the spacer 113 is located on the sidewall of the gate structure 112. Furthermore, there are isolation structures 119 located in the substrate 100 and adjacent to the semiconductor device 110.

The metal silicide layer 115 on the gate electrode 114 and the metal silicide layer 118 on the source/drain region 111 are predetermined to be the electrically connecting regions for electrically connecting with the conductive devices formed in the later manufacturing process.

Thereafter, a conformal adhesion layer 120 is formed over the substrate 100. The conformal adhesion layer 120 can be, for example but not limited to, made of silicon nitride. Also, the method for forming the conformal adhesion layer 120 comprises low pressure chemical vapor deposition (LPCVD). Then, a dielectric layer 122 is formed on the conformal adhesion layer 120. The dielectric layer 122 can be, for example but not limited to, made of silicon oxide, phosphorous silicon glass or boron-phosphorous silicon glass. Furthermore, the method for forming the dielectric layer 122 comprises chemical vapor deposition (CVD). A chemical mechanical polishing process (CMP) is performed to planarize the dielectric layer 122 in order to increase the process window for the later performed processes. Notably, because the conformal adhesion layer 120 is located between the metal silicide layer 115 and the dielectric layer 122 and between the metal silicide layer 118 and the dielectric layer 122, the dielectric layer 122 can be protected from being stripped away from the substrate 100 due to the shear stress induced by the CMP process. Furthermore, the phenomenon that the voids and defects happen at the interface between the dielectric layer 122 and the metal silicide layers 115 and 118 can be avoided.

As shown in FIG. 1B, at least one opening 124 is formed to penetrating through the dielectric layer 122 and the conformal adhesion layer 120 and exposes a portion of the metal silicide layer 115 and the metal silicide layer 118 respectively. The method for forming the opening 124 comprises steps of forming a patterned photoresist layer (not shown) over the substrate 100, performing an etching process by using the patterned photoresist layer as a mask and then removing the patterned photoresist layer.

Then, a conformal barrier layer 126 is formed over the substrate 100. The conformal barrier layer 126 can be, for example but not limited to, formed from titanium/titanium nitride. The method for forming the conformal barrier layer 126 comprises steps of sputtering a titanium layer over the substrate 100 and then performing a thermal process on the substrate 100 under a nitrogen rich environment.

Thereafter, a conductive plug 128 is formed in the opening 124. The conductive plug 128 can be, for example but not limited to, made of tungsten. The method for forming the conductive plug 124 comprises steps of forming a tungsten layer (not shown) over the substrate 100 using CVD and then performing a CMP process to remove a portion of the tungsten layer until the barrier layer 126 is exposed.

In the present invention, the conformal adhesion layer is located between two heterogeneous material layers which possess poor adhesion ability to each other so that the heterogeneous material layers can be protected from being ripped off from each other due to the shear stress caused by the CMP process. Therefore, the phenomenon that the void and the defects exist between the heterogeneous material layers can be avoided and the electrical performance of the device is stable.

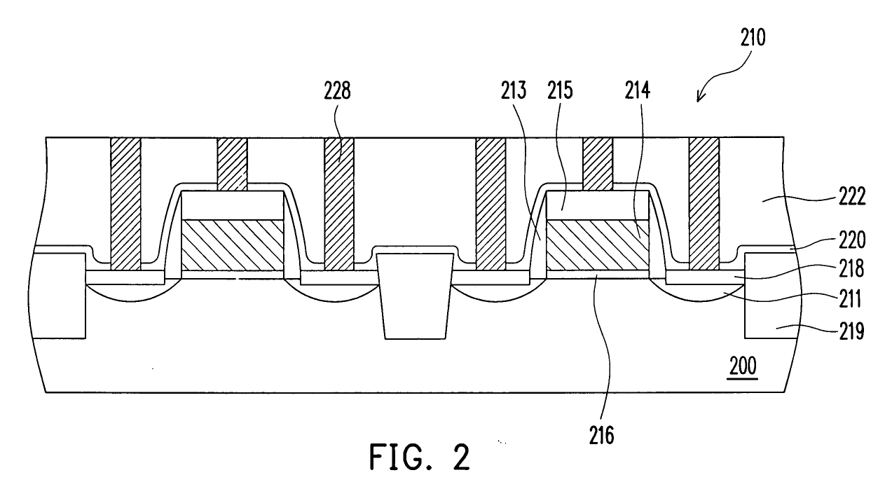

FIG. 2 is a cross-sectional view showing an interconnect structure according to one preferred embodiment of the present invention. As shown in FIG. 2, the interconnect structure is located on a substrate 200, wherein the substrate 200 has a semiconductor device 210. The semiconductor device 210 can be, for example but not limited to, a logic device. Preferably, the semiconductor device 210 is a logic device, such as a driver of the thin-film-transistor liquid crystal display, operated at a high voltage level. Moreover, the semiconductor device 210 is composed of a source/drain region 211, a tunnel dielectric layer 216, a gate electrode 214, a metal silicide layer 215 and a spacer 213. The gate electrode 214 is located over the substrate and the metal silicide layer 215 is located on the gate electrode 214. Further, the tunnel dielectric layer 216 is located between the gate electrode 214 and the substrate 100. The tunnel dielectric layer 216, the gate electrode 214 and the metal silicide layer 215 together form a gate structure and the spacer 213 is located on the sidewall of the gate structure 213. The gate electrode 214 can be, for example but not limited to, made of doped polysilicon and the metal silicide layer 215 can be, for example but not limited to, made of tungsten silicide. The source/drain region 211 is located in the substrate 200 adjacent to the gate structure. There is a metal silicide layer 218 formed on the source/drain region 211. Moreover, the metal silicide layer 218 can be, for example but not limited to, made of tungsten silicide. The metal silicide layer 215 on the gate electrode 214 and the metal silicide layer 218 on the source/drain region 211 are predetermined to be the electrically connecting regions for electrically connecting with the conductive devices formed in the later manufacturing process. Furthermore, there are isolation structures 219 located in the substrate 100 and adjacent to the semiconductor device 210. In this preferred embodiment, only one semiconductor device 210 is used to illustrate spirit of the present invention. However, in the application, there are several semiconductor devices are disposed on the substrate 200.

As shown in FIG. 2, a conformal adhesion layer 220 is located over the substrate 200. The conformal adhesion layer 220 can be, for example but not limited to, made of silicon nitride and the thickness of the conformal adhesion layer 220 is about 200-500 angstroms. A dielectric layer 222 is located on the conformal adhesion layer 220. The dielectric layer 222 can be, for example but not limited to, made of silicon oxide, phosphorous silicon glass or boron-phosphorous silicon glass. Also, a conductive plug 228 is located in the dielectric layer 222 and the conformal adhesion layer 220. The conductive plug 228 can be, for example but not limited to, made of tungsten. The conductive plug 228 is electrically connected to the metal silicide layers 215 and 218 respectively.

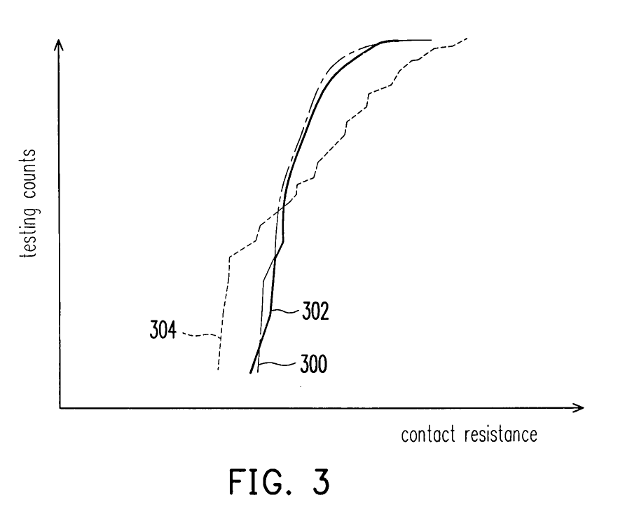

FIG. 3 is a testing counts-contact resistance diagram. As shown FIG. 3, the curve 300 and the curve 302 indicate the testing results of the semiconductor devices according to the present invention and the curve 304 indicates the testing result of a semiconductor device without having a conformal adhesion layer between the heterogeneous material layers. With the increasing of the number of the testing runs, the contact resistance variation of the semiconductor devices according to the present invention is less than that of the semiconductor device without using the conformal adhesion layer between the dielectric layer and the electrically connecting region. That is, the electrical performance of the semiconductor device according to the present invention is more stable than that of the semiconductor device formed by using the conventional manufacturing process.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A method for manufacturing an interconnect structure suitable for a substrate having a semiconductor device formed thereon, wherein the semiconductor device possesses a metal silicide layer predetermined as an electrically connecting region, the method comprising:
forming a conformal adhesion layer over the substrate;
forming a dielectric layer on the conformal adhesion layer;
performing a chemical mechanical polishing process to planarize the dielectric layer;
forming an opening penetrating through the dielectric layer and the conformal adhesion layer, wherein the opening exposes a portion of the metal silicide layer; and
forming a conductive plug in the opening.

2. The method of claim 1, wherein the conformal adhesion layer is made of silicon nitride.

3. The method of claim 2, wherein the method for forming the conformal adhesion layer comprises a low pressure chemical vapor deposition (LPCVD).

4. The method of claim 1, wherein the thickness of the conformal adhesion layer is about 200-500 angstroms.

5. The method of claim 1, wherein the material of the dielectric layer is selected from a group consisting of silicon oxide, phosphorous silicon glass and boron-phosphorous silicon glass.

6. The method of claim 1, wherein the semiconductor device can be a logic device operated at a high voltage level.

7. The method of claim 1, wherein the metal silicide layer is located at a gate electrode of the semiconductor device.

8. The method of claim 7, wherein the gate electrode is made of a doped polysilicon.

9. The method of claim 1, wherein the metal silicide layer is located at a source/drain region of the semiconductor device.

10. The method of claim 1, wherein the metal silicide is made of tungsten silicide.

11. The method of claim 1, before the conductive plug is formed, further comprising a step of forming a conformal barrier layer over the substrate.

12. The method of claim 11, wherein the conformal barrier layer is made of titanium/titanium nitride.

13. The method of claim 12, wherein the conductive plug is made of tungsten.

14. An interconnect structure on a substrate having a logic device formed thereon, wherein the logic device possesses a metal silicide layer predetermined as an electrically connecting region, the interconnect structure comprising:
a conformal adhesion layer located over the substrate;
a dielectric layer located on the conformal adhesion layer; and
a conductive plug penetrating through the dielectric layer and the conformal adhesion layer, wherein the conductive plug is electrically connected to the metal silicide layer.

15. The interconnect structure of claim 14, wherein the conformal adhesion layer is made of silicon nitride.

16. The interconnect structure of claim 14, wherein the thickness of the conformal adhesion layer is about 200-500 angstroms.

17. The interconnect structure of claim 14, wherein the logic device can be operated at a high voltage level.

18. The interconnect structure of claim 14, wherein the metal silicide layer is located at a gate electrode of the logic device.

19. The interconnect structure of claim 14, wherein the metal silicide layer is located at a source/drain region of the logic device.

20. The interconnect structure of claim 14, wherein the metal silicide layer is made of tungsten silicide.
